(19) United States
(12) Patent Application Publication
(10) Pub. No.: US 2025/0137127 A1
(43) Pub. Date: May 1, 2025

(54) METHOD FOR FORMING A RARE-EARTH-CONTAINING LAYER, APPARATUS, AND STRUCTURE

(71) Applicant: ASM IP Holding B.V., Almere (NL)

(72) Inventors: Rochelle Lee, Tempe, AZ (US); Giuseppe Alessio Verni, Ismaning (DE); Petro Deminakyi, Espoo (FI); Hoang Nguyen, Espoo (FI)

(21) Appl. No.: 18/930,631

(22) Filed: Oct. 29, 2024

Related U.S. Application Data
(60) Provisional application No. 63/546,615, filed on Oct. 31, 2023.

(51) Int. Cl. C23C 16/455; C23C 16/32; C23C 16/34

(52) U.S. Cl. CPC C23C 16/45553; C23C 16/32; C23C 16/34

(57) ABSTRACT

This disclosure relates to a method for forming a rare-earth-containing layer, an apparatus, and a structure. The method comprises providing a substrate within a process chamber and depositing the rare-earth-containing layer over the substrate. The process of depositing the rare-earth-containing layer comprises providing a rare-earth precursor into the process chamber, providing a metal precursor into the process chamber, and providing one or more non-metal element reactants into the process chamber. The apparatus comprises a process chamber, a precursor supply unit for supplying a rare-earth precursor and a metal precursor into the process chamber, and a reactant supply unit for supplying one or more non-metal element reactants into the process chamber.

### CROSS-REFERENCE TO RELATED APPLICATION(S)

This Application claims the benefit of U.S. Provisional Application 63/546,615 filed on Oct. 31, 2023, the entire contents of which are incorporated herein by reference.

### FIELD OF INVENTION

The present disclosure generally relates to methods and systems suitable for forming a layer on a surface of a substrate and to structures including the layer. More particularly, the disclosure relates to methods and systems for forming layers that allow controlling the threshold voltage of metal-oxide-semiconductor field-effect transistors (MOSFETs) and to structures formed using the methods and systems.

### BACKGROUND OF THE DISCLOSURE

The scaling of semiconductor devices, such as, for example, complementary metal-oxide-semiconductor (CMOS) devices, has led to significant improvements in speed and density of integrated circuits. However, conventional device scaling techniques face significant challenges for future technology nodes. For example, one challenge has been finding suitable dielectric stacks that form an insulating barrier between a gate and a channel of a field effect transistor. One particular problem in this regard is controlling the threshold voltage of field effect transistors.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

According to a first aspect, a method for forming a rare-earth-containing layer is provided. the method comprises providing a substrate within a process chamber and depositing the rare-earth-containing layer over the substrate. The process of depositing the rare-earth-containing layer comprises providing a rare-earth precursor into the process chamber, providing a metal precursor into the process chamber, and providing one or more non-metal element reactants into the process chamber. The rare-earth-containing layer comprises a rare-earth element, a metal element different from the rare-earth element, a first non-metal element, and a second non-metal element different from the first non-metal element.

According to a second aspect, an apparatus is provided. The apparatus comprises a process chamber, a precursor supply unit for supplying a rare-earth precursor and a metal precursor into the process chamber, a reactant supply unit for supplying one or more non-metal element reactants into the process chamber, and a control unit configured to control at least the precursor supply unit and the reactant supply unit to conduct a method in accordance with the first aspect.

According to a third aspect, a structure is provided. The structure comprises a substrate and a rare-earth-containing layer over the substrate. The rare-earth-containing layer comprises a rare-earth element, a metal element different from the rare-earth element, a first non-metal element, and a second non-metal element different from the first non-metal element.

The embodiments discussed below may relate to any of the aspects above, mutatis mutandis.

In some embodiments, the rare-earth element is selected from the group consisting of cerium, dysprosium, erbium, europium, gadolinium, holmium, lanthanum, lutetium, neodymium, praseodymium, promethium, samarium, scandium, terbium, thulium, ytterbium, and yttrium.

In some embodiments, the rare-earth precursor comprises at least one of cerium, dysprosium, erbium, europium, gadolinium, holmium, lanthanum, lutetium, neodymium, praseodymium, promethium, samarium, scandium, terbium, thulium, ytterbium, and yttrium.

In some embodiments, the rare-earth precursor comprises the rare-earth element in oxidation state +3 or in oxidation state +4.

In some embodiments, the rare-earth precursor comprises a cyclopentadienyl ligand, for example, an unsubstituted cyclopentadienyl ligand or a substituted cyclopentadienyl ligand, such as an alkylsilyl-substituted cyclopentadienyl ligand, e.g., an isopropylcyclopentadienyl ligand.

In some embodiments, the metal element is selected from the group consisting of group 3 metals, e.g., scandium and yttrium; group 4 metals, e.g., titanium and zirconium; group 5 metals, e.g., vanadium and niobium; group 6 metals, e.g., chromium and molybdenum; group 7 metals, e.g. manganese; group 8 metals, e.g., iron and ruthenium; group 9 metals, e.g., cobalt and rhodium; group 10 metals, e.g., nickel and palladium; group 11 metals, e.g., copper and silver; group 12 metals, e.g., zinc and cadmium; group 13 metals, e.g., aluminium, gallium, and indium; and lanthanides; e.g., cerium, dysprosium, erbium, europium, gadolinium, holmium, lanthanum, lutetium, neodymium, praseodymium, promethium, samarium, terbium, thulium, and ytterbium.

In some embodiments, the metal precursor comprises at least one of a group 3 metal, e.g., scandium or yttrium; a group 4 metal, e.g., titanium or zirconium; a group 5 metal, e.g., vanadium or niobium; a group 6 metal, e.g., chromium or molybdenum; a group 7 metal, e.g. manganese; a group 8 metal, e.g., iron or ruthenium; a group 9 metal, e.g., cobalt or rhodium; a group 10 metal, e.g., nickel or palladium; a group 11 metal, e.g., copper or silver; a group 12 metal, e.g., zinc or cadmium; a group 13 metal, e.g., aluminium, gallium, or indium; and lanthanides; e.g., cerium, dysprosium, erbium, europium, gadolinium, holmium, lanthanum, lutetium, neodymium, praseodymium, promethium, samarium, terbium, thulium, or ytterbium.

In some embodiments, the metal precursor comprises the metal element in oxidation state +3 or in oxidation state +4.

In some embodiments, the metal precursor comprises a cyclopentadienyl ligand, for example, an unsubstituted cyclopentadienyl ligand or a substituted cyclopentadienyl ligand, such as an alkylsilyl-substituted cyclopentadienyl ligand, e.g., an isopropylcyclopentadienyl ligand.

In some embodiments, the first non-metal element and/or the second non-metal element is selected from the group consisting of boron, group 14 non-metals, e.g., carbon or silicon; group 15 non-metals, e.g., nitrogen, phosphorus, or arsenide; group 16 non-metals, e.g., oxygen, sulfur, selenium, or tellurium; and group 17 non-metals, e.g., fluorine, chlorine, bromine, or iodine.

In some embodiments, the process of providing one or more non-metal element reactants comprises providing a first non-metal element reactant and providing a second non-metal element reactant different from the first non-metal element reactant.

In some embodiments, the first non-metal element reactant comprises at least one of boron, a group 14 non-metal, e.g., carbon or silicon; a group 15 non-metal, e.g., nitrogen, phosphorus, or arsenide; a group 16 non-metal, e.g., oxygen, sulfur, selenium, or tellurium; and a group 17 non-metal, e.g., fluorine, chlorine, bromine, or iodine; and the second non-metal element reactant comprises at least one other of boron, a group 14 non-metal, e.g., carbon or silicon; a group 15 non-metal, e.g., nitrogen, phosphorus, or arsenide; a group 16 non-metal, e.g., oxygen, sulfur, selenium, or tellurium; and a group 17 non-metal, e.g., fluorine, chlorine, bromine, or iodine.

In some embodiments, the process of providing one or more non-metal element reactants comprises providing a non-metal multi-element reactant comprising the first non-metal element and the second first non-metal element.

In some embodiments, the substrate has an outer surface and comprises a dielectric layer extending along the outer surface.

In some embodiments, the dielectric layer comprises a high-k dielectric material, for example, a high-k silicate, e.g., hafnium silicate; a high-k oxide, e.g., hafnium dioxide, tantalum oxide, or zirconium dioxide; or a mixture, e.g., a solid solution or mixed oxide, thereof.

In some embodiments, the method comprises forming a first conductive layer prior to depositing the rare-earth-containing layer.

In some embodiments, the first conductive layer comprises a first transition metal compound.

In some embodiments, the first transition metal compound comprises a first non-metal constituent element different from the first non-metal element and/or the second first non-metal element.

In some embodiments, the first transition metal compound comprises a first transition metal element different from the rare-earth element and/or the metal element.

In some embodiments, the first transition metal compound is implemented as a first transition metal carbide and/or a first transition metal nitride.

In some embodiments, the first conductive layer has a thickness greater than or equal to 0.1 nm, or to 0.5 nm, or to 0.8 nm and/or less than or equal to 8 nm, or to 6 nm or to 5 nm.

In some embodiments, the method comprises forming a second conductive layer after depositing the rare-earth-containing layer.

In some embodiments, the second conductive layer comprises a second transition metal compound.

In some embodiments, the second transition metal compound comprises a second non-metal constituent element different from the first non-metal element and/or the second first non-metal element.

In some embodiments, the second transition metal compound comprises a second transition metal element different from the rare-earth element and/or the metal element.

In some embodiments, the second transition metal compound is implemented as a second transition metal carbide and/or a second transition metal nitride.

In some embodiments, the second conductive layer has a thickness greater than or equal to 0.5 nm, or to 1 nm, or to 2 nm and/or less than or equal to 40 nm, or to 30 nm or to 20 nm.

In some embodiments, the process of depositing the rare-earth-containing layer comprises providing a first hydrogen-containing substance after the process of providing a rare-earth precursor and/or providing a second hydrogen-containing substance after the process of providing a metal precursor.

In some embodiments, the first hydrogen-containing substance and/or the second hydrogen-containing substance comprises hydrogen gas.

In some embodiments, the rare-earth-containing layer is formed at a deposition temperature greater than or equal to 100° C., or 200° C., or 300° C., or 350° C. and/or less than or equal to 550° C., or to 500° C., or to 450° C., or to 400° C.

In some embodiments, the rare-earth-containing layer has a thickness greater than or equal to 0.1 nm, or to 0.5 nm, or to 1 nm, or to 2 nm and/or less than or equal to 10 nm, or to 8 nm, or to 5 nm.

In some embodiments, the rare-earth-containing layer is formed in a cross-flow process chamber, a showerhead process chamber, or a hot-wall process chamber.

In some embodiments, the process of providing a rare-earth precursor comprises holding the rare-earth precursor in a rare-earth precursor vessel and transporting the rare-earth precursor to the process chamber using a rare-earth precursor carrier gas, and/or the process of providing a metal precursor comprises holding the metal precursor in a metal precursor vessel and transporting the metal precursor to the process chamber using a metal precursor carrier gas.

In some embodiments, the rare-earth precursor carrier gas and/or the metal precursor carrier gas is independently selected from the group consisting of nitrogen gas, helium gas, neon gas, argon gas, krypton gas, xenon gas, radon gas, and mixtures thereof.

In some embodiments, the rare-earth precursor and/or the metal precursor is held at a vessel temperature greater than or equal to 20° C., or 50° C., or 70° C., or 350° C. and/or less than or equal to 200° C., or to 150° C., or to 130° C.

In some embodiments, the process of depositing the rare-earth-containing layer is implemented as a chemical vapor deposition process, for example, a cyclic chemical vapor deposition process, such as an atomic layer deposition process, e.g., a temporal atomic layer deposition process.

In some embodiments, the process of depositing the rare-earth-containing layer is implemented as a thermal deposition process or an active-species-enhanced deposition process, such as a radical-enhanced deposition process.

In some embodiments, the structure forms at least part of a semiconductor device, such as a semiconductor transistor, e.g., a metal-oxide-semiconductor field-effect transistor.

In some embodiments, the structure is formed using a method in accordance with the first aspect.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

A more complete understanding of the embodiments of the present disclosure may be derived by referring to the detailed description and claims when considered in connection with the following illustrative figures:

FIG. 1A illustrates a method for forming a rare-earth-containing layer,

FIG. 1B shows another method for forming a rare-earth-containing layer,

FIG. 2 depicts an apparatus, and

FIG. 3 shows a [structure for a semiconductor device].

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various processes, systems, and configurations, and other features, functions, acts, and/or properties disclosed herein, as well as any and all equivalents thereof.

In this specification, a “process” may refer to a series of one or more steps, leading to an end result. Additionally, a “step” may refer to a measure taken in order to achieve one or more pre-defined end results. Generally, a process may be a single-step or a multistep process. Additionally, a process may be divisible to a plurality of sub-processes, wherein individual sub-processes of such plurality of sub-processes may or may not share common steps.

In this specification, a “chemical vapor deposition process” or “CVD process” may refer to a coating process, wherein one or more gaseous compounds decompose to deposit a layer onto a substrate. Further, a “cyclic chemical vapor deposition process” or “cyclic CVD process” may refer to a CVD process comprising sequentially and/or cyclically providing precursors, and/or reactants, and/or active species to deposit said layer onto said substrate.

Throughout this specification, an “atomic layer deposition process” or “ALD process” may refer to a cyclic CVD process, comprising purging a process chamber or a process station between provision of precursors, and/or reactants, and/or active species. Typically, purging may be accomplished by flushing said process chamber or process station with an inert gas. Additionally or alternatively, an “atomic layer deposition process” or “ALD process” may refer to a cyclic CVD process suitable for or configured to deposit a conformal layer, e.g., a layer with a step coverage (SC) of at least 95%, or 99%, or about 100% for a feature with an aspect ratio (AR) of 3:1, or 5:1, or 10:1, onto a substrate. The term “atomic layer deposition”, as used herein, may or may not also refer to processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es). Further, a “temporal atomic layer process” or “temporal ALD process” may refer to an ALD process, wherein the process of purging a process station comprises a temporal purging step during which provision of precursors, and/or reactants, and/or active species is discontinued. Additionally or alternatively, a “temporal atomic layer process” or “temporal ALD process” may refer to an ALD process, wherein a substrate onto which a layer is deposited is held immobile during deposition.

Typically, for ALD processes, during each cycle, a precursor is introduced to a process chamber or a process station and is chemisorbed onto a deposition surface (e.g., a substrate surface that can include a previously deposited material from a previous ALD cycle or other material) and forming material, for example, about a monolayer or sub-monolayer of material, or several monolayers of material, or a plurality of monolayers of material, that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant may be capable of further reaction with the precursor. Purging steps may be utilized during one or more cycles, e.g., after each step of each cycle, to remove any excess precursor from a process chamber or process station and/or remove any excess reactant and/or reaction byproducts from said process chamber or process station.

In this disclosure, an “active-species-enhanced” deposition process may refer to a CVD process, wherein one or more gaseous compounds that decompose to deposit a layer are exposed to active species during said deposition process, whereas a “thermal deposition process” may refer to non-active-species-enhanced CVD process. Herein, “active species” may refer to unstable molecular entities formed in plasma, via interactions with catalytic material(s) at elevated temperatures, and/or by other suitable means. Additionally or alternatively, active species may refer to ions and/or (free) radicals. Further, an “ion” may refer to an atomic or molecular particle possessing a net electric charge, and/or a “radical” may refer to an atomic or molecular particle possessing an unpaired electron. In some embodiments, an active-species-enhanced deposition process may be implemented as a radical-enhanced deposition process, wherein the active species to which one or more gaseous compounds decomposing to deposit a layer may comprise, comprise primarily, comprise predominantly, comprise essentially, consist substantially of, consist essentially of, or consist of radicals.

Throughout this disclosure, a “layer” or “film” may refer to a structure having a certain thickness formed on a surface. A layer may be continuous or discontinuous. A film or layer may or may not be constituted by a discrete single film or layer having certain characteristics or multiple films or layers. A boundary between adjacent films or layers may or may not be clear and may or may not be established based on physical, chemical, and/or any other characteristics, formation processes or sequences, and/or functions or purposes of the adjacent films or layers. A layer or film may or may not comprise pinholes. A layer of film may or may not be porous.

In this disclosure, a “substrate” may refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as GaAs, and can include one or more layers overlying or underlying the bulk material. Further, the substrate can include various structures, such as recesses, vias, lines, and the like formed within or on at least a portion of a layer of the substrate.

Herein, a “process chamber” may refer to a chamber suitable for or configured to enable performing a process on a substrate. Additionally or alternatively, a process chamber may refer to a vacuum chamber within which a process may be performed. A process chamber may comprise one or more process stations.

Herein, a “process station” may refer to a location suitable for or configured to hold a substrate so that a process may be performed on the substrate. Additionally or alternatively, a process station may refer to a portion of a process chamber. In some embodiments, individual process stations of a process chamber may be arranged in gas isolation from each other or configured to be in gas isolation from each other while one or more substrates are processed inside one or more of the individual process stations. In such embodiments, individual process stations of a process chamber may be arranged in gas isolation by way of physical barriers, and/or gas bearings, and/or gas curtains. In some embodiments, after or concurrently with the placement of a substrate in a process station, said process station may be arranged in gas isolation. In some embodiments, after a substrate has been processed in a process station, said process station may be brought out of gas isolation such that said substrate may be removed from the process station. Typically, a plurality of substrates may be placed in a shared intermediate space of a process chamber for moving individual substrates of said plurality of substrates from process station to another.

Throughout this specification, a “control unit” may refer to any combination of individual controller devices and processing electronics that may be integrated with or connected to other devices. In some embodiments, a control unit may include a centralized controller that controls the operation of multiple devices or components. In some embodiments, a control unit may be understood to include a plurality of distributed controllers that control the operation of one or more devices or components. Generally, control sequences may be hardwired or programmed into a control unit. Memory devices of a control unit may include non-transitory computer-readable media, such as physical computer storage including hard drives, solid state memory, random access memory (RAM), read only memory (ROM), optical disc, volatile or non-volatile storage, combinations of the same and/or the like. Said non-transitory computer-readable media may provide instructions to one or more processors. It will be appreciated that the instructions may be for any of the actions described herein, such that processing of the instructions by the one or more processors causes semiconductor processing apparatus to perform those actions.

In this disclosure, “gas” may refer to a material that is a gas at normal temperature and pressure (NTP), a vaporized solid and/or a vaporized liquid. The term “gas” may refer to a gas composed of a single chemical substance or a mixture of chemical substances. A gas other than the process gas, i.e., a gas introduced without passing through a gas distribution assembly, other gas distribution device, or the like, may be used, for example, for sealing a process station, and can include a seal gas, such as a rare gas.

In this specification, a “precursor” or “reactant” may refer to a compound that participates in a chemical reaction that produces another compound, for example, a compound that constitutes a film matrix or a main skeleton of a film.

This disclosure may use the following abbreviations: RE-M may refer to rare earth metal, Cp may refer to cyclopentadienyl, MeCp may refer to methylcyclopentadienyl, EtCp may refer to ethylcyclopentadienyl, iPrCp may refer to isopropylcyclopentadienyl, nPrCp may refer to n-propyl cyclopentadienyl, tBuCp may refer to tert-butyl cyclopentadienyl, and TMSCp may refer to trimethylsilylcyclopentadienyl. Me may refer to methyl; Et may refer to ethyl; iPr may refer to isopropyl; nPr may refer to n-propyl; nBu may refer to n-butyl; acac may refer to acetylacetonate; hfac may refer to hexafluoroacetylacetonate; N^{R, R}′ R″—amd″ or N^{R} R″—amd when R equals R′ refers to the amidinate ligand [R—N—C(R″)═N—R′], wherein R, R′ and R″ are C1-C5 hydrocarbyls, e.g. C1-C5 hydrocarbyls; R₂—fmd″ may refer to an amidinate ligand in which R equals R′ and R″ equals H; R₂—amd″ may refer to an amidinate ligand in which R equals R′, and R″ equals CH₃; thd may refer to 2,2,6,6-tetramethylheptane-3,5-dionate; phen may refer to phenanthroline.

The presently described methods and devices may be useful for controlling the threshold voltage of field effect transistors. In some embodiments, the present methods and devices may be useful for controlling the threshold voltage of n-channel field effect transistors, such as n-channel metal-oxide semiconductor field effect transistors, such as n-channel gate-all-around metal oxide semiconductor field effect transistors. In some embodiments, the present methods and devices may be useful for controlling the threshold voltage of p-channel field effect transistors, such as p-channel metal-oxide semiconductor field effect transistors, such as p-channel gate-all-around metal oxide semiconductor field effect transistors. In some embodiments, the present methods and devices may be useful for inducing a negative flatband voltage shift for metal oxide semiconductor field effect transistors (MOSFETs). Thus, the present methods and devices may be particularly useful for decreasing the gate voltage at which a conductive channel is produced between the source and drain of an n-MOSFET. The n-MOSFET may, for example, be comprised in a CMOS-based integrated circuit. Additionally or alternatively, the present methods and devices may be particularly useful for increasing the gate voltage at which a conductive channel is produced between the source and drain of a p-MOSFET. The p-MOSFET may, for example, be comprised in a CMOS-based integrated circuit. In other words, the present methods and devices may be particularly useful for decreasing the voltage at which an n-MOSFET switches from an off-state to an on-state, and for increasing the voltage at which a p-MOSFET switches from an off-state to an on-state. Similarly, the present methods and devices may be particularly useful for decreasing the flat band voltage of n-MOSFETS, and for increasing the flat band voltage of p-MOSFETS. The presently methods and devices may be particularly useful for the manufacture of n-MOSFETS and p-MOSFETS with a gate-all-around architecture. Additionally or alternatively, the present methods and devices may be of particular use in the context of systems-on-a-chip.

In some embodiments, the present methods and devices may be useful for inducing a positive flatband voltage shift for metal oxide semiconductor field effect transistors (MOSFETs). Thus, the present methods and devices may be useful for increasing the gate voltage at which a conductive channel is produced between the source and drain of an n-MOSFET. The n-MOSFET may, for example, be comprised in a CMOS-based integrated circuit. Additionally or alternatively, the present methods and devices may be particularly useful for decreasing the gate voltage at which a conductive channel is produced between the source and drain of a p-MOSFET. The p-MOSFET may, for example, be comprised in a CMOS-based integrated circuit. In other words, the present methods and devices may be particularly useful for increasing the voltage at which an n-MOSFET switches from an off-state to an on-state, and for decreasing the voltage at which a p-MOSFET switches from an off-state to an on-state. Similarly, the present methods and devices may be particularly useful for increasing the flat band voltage of n-MOSFETS, and for decreasing the flat band voltage of p-MOSFETS. The presently described methods and devices may be particularly useful for the manufacture of n-MOSFETS and p-MOSFETS with a gate-all-around architecture. Additionally or alternatively, the present methods and devices may be of particular use in the context of systems-on-a-chip.

Throughout this specification, a material composition is abbreviated by means of a chemical formula, the chemical formula may or may not refer to said material having a stoichiometric composition. In some embodiments, a chemical formula may refer to a stoichiometric composition in accordance with that to be inferred from said chemical formula. In other embodiments, a chemical formula may refer to a stoichiometric composition different form that to be inferred from said chemical formula. In yet other embodiments, a chemical formula may refer to a non-stoichiometric composition. For example, when titanium nitride is abbreviated as “TiN”, the term TiN can mean a titanium and nitrogen containing material in which titanium and nitrogen are present in a 1:1 ratio, or in any other suitable ratio, such as 0.8:1, 0.9:1, 0.95:1, 1:1.05, 1:1.1, 1.2, 1.5, and so forth.

Described herein is a method for forming a rare-earth-containing layer. The method comprises providing a substrate within a process chamber. A suitable substrate includes a monocrystalline silicon wafer, e.g. a p-type monocrystalline silicon wafer. The methods further comprise depositing the rare-earth-containing layer over the substrate. The process of depositing the rare-earth-containing layer comprises providing a rare-earth precursor into the process chamber, providing a metal precursor into the process chamber, and providing one or more non-metal element reactants into the process chamber. The rare-earth-containing layer comprises a rare-earth element, a metal element different from the rare-earth element, a first non-metal element; and a second non-metal element different from the first non-metal element.

In some embodiments, providing a rare-earth precursor and/or providing a metal precursor precedes at least part of the process of providing one or more non-metal element reactants. This notwithstanding, and in other embodiments, the process of providing one or more non-metal element reactants may at least partly precede the process(es) of providing a rare-earth precursor and/or providing a metal precursor.

In some embodiments, the rare-earth element is selected from the group consisting of cerium, dysprosium, erbium, europium, gadolinium, holmium, lanthanum, lutetium, neodymium, praseodymium, promethium, samarium, scandium, terbium, thulium, ytterbium, and yttrium.

In some embodiments, the rare-earth precursor comprises at least one of cerium, dysprosium, erbium, europium, gadolinium, holmium, lanthanum, lutetium, neodymium, praseodymium, promethium, samarium, scandium, terbium, thulium, ytterbium, and yttrium.

In some embodiments, the rare-earth precursor comprises the rare-earth element in oxidation state +3 or in oxidation state +4. Generally, a rare-earth precursor may comprise a rare-earth element in any suitable oxidation state(s), for example, +2, +3, or +4. In some embodiments, the rare-earth precursor comprises RE-M(Cp)₃, RE-M(EtCp)₃, RE-M(MeCp)₃, RE-M(iPrCp)₃, RE-M(nPrCp)₃, RE-M(nBuCp)₃, and/or RE-M(tBuCp)₃. In some embodiments, the rare-earth precursor comprises RE-M(Cp)₄, RE-M(EtCp)₄, RE-M(MeCp)₄, RE-M(iPrCp)₄, RE-M(nPrCp)₄, RE-M(nBuCp)₄, and RE-M(tBuCp)₄.

In some embodiments, the rare-earth precursor comprises a cyclopentadienyl ligand, for example, an unsubstituted cyclopentadienyl ligand or a substituted cyclopentadienyl ligand, such as an alkylsilyl-substituted cyclopentadienyl ligand, e.g., an isopropylcyclopentadienyl ligand. In some embodiments, the alkylsilyl-substituted cyclopentadienyl ligand is selected from trimethylsilyl cyclopentadienyl, triethylsilyl cyclopentadienyl, and triisopropylsilyl cyclopentadienyl. In some embodiments, the rare-earth precursor comprises RE-M(TMSCp)₃. In some embodiments, the rare-earth precursor comprises a C1 to C4 alkyl-substituted cyclopentadienyl ligand, such as EtCp, MeCp, iPrCp, nBuCp, or tBuCp.

In some embodiments, the rare-earth precursor comprises a rare earth metal diketonate. In some embodiments, the rare-earth precursor comprises a guanidinate ligand. In some embodiments, the rare-earth precursor is selected from the list consisting of: RE-M(acac)₄, RE-M(hfac)₃, RE-M(hfac)₄, RE-M(thd)₃, RE-M(thd)₄, and RE-M(thd)₃phen.

In some embodiments, the rare-earth precursor comprises an amidinate ligand. In some embodiments, the rare-earth precursor comprises a formamidinate (fmd) ligand. In some embodiments, the rare-earth precursor comprises an acetamidinate (amd) ligand. In some embodiments, the rare-earth precursor comprises an amidinate ligand selected from R₂—amd and R₂—fmd, wherein R is a linear or branched C1 to C4 alkyl. In some embodiments, the rare-earth precursor comprises a compound of the form RE-M(R¹₂—amd)₃, RE-M(R¹₂—fmd)₃, RE-M (R²₂Cp)₂(R¹₂—amd), and RE-M(R²₂Cp)₂(R¹₂—fmd), RE-M(R¹₂—amd)₄, RE-M(R¹₂—fmd)₄, RE-M (R²₂Cp)₃(R¹₂—amd), RE-M(R²₂Cp)₂(R¹₂—amd)₂, RE-M(R²₂Cp)(R¹₂—amd)₃, RE-M (R²₂Cp)₃(R¹₂—fmd), RE-M(R²₂Cp)₂(R¹₂—fmd)₂, and RE-M(R²₂Cp)(R¹₂—fmd)₃, wherein R¹ and R² are independently selected from a linear or branched C1 to C4 alkyl. In some embodiments, the rare-earth precursor comprises at least one of RE-M(iPr₂—amd)₃, RE-M(tBu₂—amd)₃, and RE-M (iPrCp)₂(iPr₂—amd), RE-M(Cp)₂(iPr₂—amd), RE-M(MeCp)₂(iPr₂—amd), RE-M(EtCp)₂(iPr₂—amd), RE-M(nPrCp)₂(iPr₂—amd), RE-M(tBuCp)₂(iPr₂—amd), RE-M(iPr₂—amd)₄, RE-M(tBu₂—amd)₄, RE-M(iPrCp)₃(iPr₂—amd), RE-M(iPrCp)₂(iPr₂—amd)₂, RE-M(iPrCp) (iPr₂—amd)₃, RE-M (Cp)₃(iPr₂—amd), RE-M(Cp)₂(iPr₂—amd)₂, RE-M(Cp) (iPr₂—amd)₃, RE-M(MeCp)₃(iPr₂—amd), RE-M(MECp)₂(iPr₂—amd)₂, RE-M(MeCp) (iPr₂—amd)₃, RE-M(EtCp)₃(iPr₂—amd), RE-M (EtCp)₂(iPr₂—amd)₂, RE-M(EtCp) (iPr₂—amd)₃, RE-M(nPrCp)₃(iPr₂—amd), RE-M (nPrCp)₂(iPr₂—amd)₂, RE-M(nPrCp) (iPr₂—amd)₃, RE-M(tBuCp)₃(iPr₂—amd), RE-M (tBuCp)₂(iPr₂—amd)₂, RE-M(tBuCp) (iPr₂—amd)₃. In some embodiments, the rare-earth precursor comprises at least one of RE-M(iPr₂—fmd)₃, RE-M(tBu₂—fmd)₃, and RE-M (iPrCp)₂(iPr₂—fmd), RE-M(Cp)₂(iPr₂—fmd), RE-M(MeCp)₂(iPr₂—fmd), RE-M(EtCp)₂(iPr₂—fmd), RE-M(nPrCp)₂(iPr₂—fmd), RE-M(tBuCp)₂(iPr₂—fmd), RE-M(iPr₂—fmd)₄, RE-M(tBu₂—fmd)₄, RE-M(iPrCp)₃(iPr₂—fmd), RE-M(iPrCp)₂(iPr₂—fmd)₂, RE-M(iPrCp) (iPr₂—fmd)₃, RE-M (Cp)₃(iPr₂—fmd), RE-M(Cp)₂(iPr₂—fmd)₂, RE-M(Cp)(iPr₂——fmd)₃, RE-M(MeCp)₃(iPr₂—fmd), RE-M(MECp)₂(iPr₂—fmd)₂, RE-M(MeCp)(iPr₂—fmd)₃, RE-M(EtCp)₃(iPr₂—fmd), RE-M (EtCp)₂(iPr₂—fmd)₂, RE-M(EtCp) (iPr₂—fmd)₃, RE-M(nPrCp)₃(iPr₂—fmd), RE-M (nPrCp)₂(iPr₂—fmd)₂, RE-M(nPrCp)(iPr₂—fmd)₂, RE-M(tBuCp)₃(iPr₂—fmd), RE-M (tBuCp)₂(iPr₂—fmd)₂, and RE-M(tBuCp) (iPr₂—fmd)₃.

In some embodiments, the rare-earth precursor comprises a rare earth metal alkoxide such as RE-M(OCMe₂CH₂OMe)₄.

In some embodiments, the rare-earth precursor comprises one or more rare earth metal alkylsylilamines. An exemplary earth metal alkylsilylamine includes Ce[N(SiMe₃)₂]₃.

In some embodiments, the metal element is selected from the group consisting of group 3 metals, e.g., scandium and yttrium; group 4 metals, e.g., titanium and zirconium; group 5 metals, e.g., vanadium and niobium; group 6 metals, e.g., chromium and molybdenum; group 7 metals, e.g. manganese; group 8 metals, e.g., iron and ruthenium; group 9 metals, e.g., cobalt and rhodium; group 10 metals, e.g., nickel and palladium; group 11 metals, e.g., copper and silver; group 12 metals, e.g., zinc and cadmium; group 13 metals, e.g., aluminium, gallium, and indium; and lanthanides; e.g., cerium, dysprosium, erbium, europium, gadolinium, holmium, lanthanum, lutetium, neodymium, praseodymium, promethium, samarium, terbium, thulium, and ytterbium.

In some embodiments, the metal precursor comprises at least one of a group 3 metal, e.g., scandium or yttrium; a group 4 metal, e.g., titanium or zirconium; a group 5 metal, e.g., vanadium or niobium; a group 6 metal, e.g., chromium or molybdenum; a group 7 metal, e.g. manganese; a group 8 metal, e.g., iron or ruthenium; a group 9 metal, e.g., cobalt or rhodium; a group 10 metal, e.g., nickel or palladium; a group 11 metal, e.g., copper or silver; a group 12metal, e.g., zinc or cadmium; a group 13 metal, e.g., aluminium, gallium, or indium; and lanthanides; e.g., cerium, dysprosium, erbium, europium, gadolinium, holmium, lanthanum, lutetium, neodymium, praseodymium, promethium, samarium, terbium, thulium, or ytterbium.

In some embodiments, the metal precursor comprises the metal element in oxidation state +3 or in oxidation state +4. Generally, a metal precursor may comprise a metal element in any suitable oxidation state(s), for example, +2, +3, or +4. In some embodiments, the metal precursor comprises RE-M(Cp)₃, RE-M(EtCp)₃, RE-M(MeCp)₃, RE-M(MeCp)₃, RE-M (nPrCp)₃, RE-M(nBuCp)₃, and/or RE-M(tBuCp)₃. In some embodiments, the metal precursor comprises RE-M(Cp)₄, RE-M(EtCp)₄, RE-M(MeCp)₄, RE-M(iPrCp)₄, RE-M (nPrCp)₄, RE-M(nBuCp)₄, and RE-M(tBuCp)₄.

In some embodiments, the metal precursor comprises a cyclopentadienyl ligand, for example, an unsubstituted cyclopentadienyl ligand or a substituted cyclopentadienyl ligand, such as an alkylsilyl-substituted cyclopentadienyl ligand, e.g., an isopropylcyclopentadienyl ligand. In some embodiments, the alkylsilyl-substituted cyclopentadienyl ligand is selected from trimethylsilyl cyclopentadienyl, triethylsilyl cyclopentadienyl, and triisopropylsilyl cyclopentadienyl. In some embodiments, the metal precursor comprises RE-M(TMSCp)₃. In some embodiments, the metal precursor comprises a C1 to C4 alkyl-substituted cyclopentadienyl ligand, such as EtCp, MeCp, iPrCp, nBuCp, or tBuCp.

In some embodiments, the metal precursor comprises a rare earth metal diketonate. In some embodiments, the metal precursor comprises a guanidinate ligand. In some embodiments, the metal precursor is selected from the list consisting of: RE-M(acac)₄, RE-M(hfac)₃, RE-M (hfac)₄, RE-M(thd)₃, RE-M(thd)₄, and RE-M(thd)₃phen.

In some embodiments, the metal precursor comprises an amidinate ligand. In some embodiments, the metal precursor comprises a formamidinate (fmd) ligand. In some embodiments, the metal precursor comprises an acetamidinate (amd) ligand. In some embodiments, the metal precursor comprises an amidinate ligand selected from R₂—amd and R₂—fmd, wherein R is a linear or branched C1 to C4 alkyl. In some embodiments, the metal precursor comprises a compound of the form RE-M(R¹₂)₃, RE-M(R¹₂—fmd)₃, RE-M (R²₂Cp)₂(R¹₂—amd), and RE-M(R²₂Cp)₂(R¹₂—fmd), RE-M(R¹₂-amd)₄, RE-M(R¹₂-fmd)₄, RE-M (R²₂Cp)₃(R¹₂), RE-M(R²₂Cp)₂(R¹₂—amd)₂, RE-M(R²₂Cp)(R¹₂—amd)₃, RE-M (R²₂Cp)₃(R¹₂—fmd), RE-M(R²₂Cp)₂(R¹₂—fmd)₂, and RE-M(R²₂Cp)(R¹₂—fmd)₃, wherein R¹ and R² are independently selected from a linear or branched C1 to C4 alkyl. In some embodiments, the metal precursor comprises at least one of RE-M(iPr₂—amd)₃, RE-M(tBu₂—amd)₃,and RE-M (iPrCp)₂(iPr₂—amd), RE-M(Cp)₂(iPr₂—amd), RE-M(MeCp)₂(iPr₂—amd), RE-M(EtCp)₂(iPr₂—amd), RE-M(nPrCp)₂(iPr₂—amd), RE-M(tBuCp)₂(iPr₂—amd), RE-M(iPr₂—amd)₄, RE-M(tBu₂—amd)₄, RE-M(iPrCp)₃(iPr₂—amd), RE-M(iPrCp)₂(iPr₂—amd)₂, RE-M(iPrCp) (iPr₂—amd)₃, RE-M (Cp)₃(iPr₂—amd), RE-M(Cp)₂(iPr₂—amd)₂, RE-M(Cp) (iPr₂—amd)₃, RE-M(MeCp)₃(iPr₂—amd), RE-M(MECp)₂(iPr₂—amd)₂, RE-M(MeCp) (iPr₂—amd)₃, RE-M(EtCp)₃(iPr₂—amd), RE-M (EtCp)₂(iPr₂—amd)₂, RE-M(EtCp) (iPr₂—amd)₃, RE-M(nPrCp)₃(iPr₂—amd), RE-M (nPrCp)₂(iPr₂—amd)₂, RE-M(nPrCp) (iPr₂—amd)₃, RE-M(tBuCp)₃(iPr₂—amd), RE-M (tBuCp)₂(iPr₂—amd)₂, RE-M(tBuCp) (iPr₂—amd)₃. In some embodiments, the metal precursor comprises at least one of RE-M(iPr₂—fmd)₃, RE-M(tBu₂—fmd)₃, and RE-M(iPrCp)₂(iPr₂—fmd), RE-M(Cp)₂(iPr₂—fmd), RE-M(MeCp)₂(iPr₂—fmd), RE-M(EtCp)₂(iPr₂—fmd), RE-M (nPrCp)₂(iPr₂—fmd), RE-M(tBuCp)₂(iPr₂—fmd), RE-M(iPr₂—fmd)₄, RE-M(tBu₂—fmd)₄, RE-M (iPrCp)₃(iPr₂—fmd), RE-M(iPrCp)₂(iPr₂—fmd)₂, RE-M(iPrCp) (iPr₂—fmd)₃, RE-M(Cp)₃(iPr₂—fmd), RE-M(Cp)₂(iPr₂—fmd)₂, RE-M(Cp) (iPr₂—fmd)₃, RE-M(MeCp)₃(iPr₂—fmd), RE-M (MECp)₂(iPr₂—fmd)₂, RE-M(MeCp)(iPr₂—fmd)₃, RE-M(EtCp)₃(iPr₂—fmd), RE-M (EtCp)₂(iPr₂—fmd)₂, RE-M(EtCp) (iPr₂—fmd)₃, RE-M(nPrCp)₃(iPr₂—fmd), RE-M (nPrCp)₂(iPr₂—fmd)₂, RE-M(nPrCp)(iPr₂—fmd)₃, RE-M(tBuCp)₃(iPr₂—fmd), RE-M (tBuCp)₂(iPr₂—fmd)₂, and RE-M(tBuCp) (iPr₂—fmd)₃.

In some embodiments, the metal precursor comprises a rare earth metal alkoxide such as RE-M(OCMe₂CH₂OMe)₄.

In some embodiments, the metal precursor comprises one or more rare earth metal alkylsylilamines. An exemplary earth metal alkylsilylamine includes Ce[N(SiMe₃)₂]₃.

In some embodiments, the first non-metal element and/or the second non-metal element is selected from the group consisting of boron, group 14 non-metals, e.g., carbon or silicon; group 15 non-metals, e.g., nitrogen, phosphorus, or arsenide; group 16 non-metals, e.g., oxygen, sulfur, selenium, or tellurium; and group 17 non-metals, e.g., fluorine, chlorine, bromine, or iodine.

In some embodiments, the process of providing one or more non-metal element reactants comprises providing a first non-metal element reactant and providing a second non-metal element reactant different from the first non-metal element reactant.

In some embodiments, the first non-metal element reactant comprises at least one of boron, a group 14 non-metal, e.g., carbon or silicon; a group 15 non-metal, e.g., nitrogen, phosphorus, or arsenide; a group 16 non-metal, e.g., oxygen, sulfur, selenium, or tellurium; and a group 17 non-metal, e.g., fluorine, chlorine, bromine, or iodine; and the second non-metal element reactant comprises at least one other of boron, a group 14 non-metal, e.g., carbon or silicon; a group 15 non-metal, e.g., nitrogen, phosphorus, or arsenide; a group 16 non-metal, e.g., oxygen, sulfur, selenium, or tellurium; and a group 17 non-metal, e.g., fluorine, chlorine, bromine, or iodine.

In some embodiments, the first non-metal element reactant and/or the second non-metal element reactant comprises a halogenated C1 to C6 alkane or alkene. In some embodiments, the first non-metal element reactant and/or the second non-metal element reactant comprises C, H, and a halogen. Suitable halogens include, F, Cl, Br, and I. In some embodiments, the first non-metal element or the second non-metal element comprises one or more compounds given by the formula CₓH_{y}I_{z}, e.g., C₂H₅I, C₂H₄I₂, CH₂I₂, CHI₃, CH₃I, and/or CI₄.

In some embodiments, the process of providing one or more non-metal element reactants comprises providing a non-metal multi-element reactant comprising the first non-metal element and the second first non-metal element.

In some embodiments, the substrate has an outer surface and comprises a dielectric layer extending along the outer surface.

In some embodiments, the dielectric layer comprises a high-k dielectric material, for example, a high-k silicate, e.g., hafnium silicate; a high-k oxide, e.g., hafnium dioxide, tantalum oxide, or zirconium dioxide; or a mixture, e.g., a solid solution or mixed oxide, thereof.

In some embodiments, the method comprises forming a first conductive layer prior to depositing the rare-earth-containing layer.

In some embodiments, the first conductive layer comprises a first transition metal compound.

In some embodiments, the first transition metal compound comprises a first non-metal constituent element different from the first non-metal element and/or the second first non-metal element.

In some embodiments, the first transition metal compound comprises a first transition metal element different from the rare-earth element and/or the metal element.

In some embodiments, the first transition metal compound is implemented as a first transition metal carbide and/or a first transition metal nitride. Suitable transition metal carbides for use as a first transition metal compound include TiC, VC, HfC, TaC, ZrC, ScC, NbC. Suitable transition metal nitrides for use as a first transition metal compound include TiN, ZrN, HAN, VN, Mo, NbN, TaN, ScN, CrN, MON, and WN. In some embodiments, the first transition metal compound is implemented as titanium nitride or as titanium carbide.

In some embodiments, the first conductive layer has a thickness greater than or equal to 0.1 nm, or to 0.5 nm, or to 0.8 nm and/or less than or equal to 8 nm, or to 6 nm or to 5 nm.

In some embodiments, the method comprises forming a second conductive layer after depositing the rare-earth-containing layer.

In some embodiments, the second conductive layer comprises a second transition metal compound. In some embodiments, the second transition metal compound is different from the first transition metal compound of a first conductive layer.

In some embodiments, the second transition metal compound comprises a second non-metal constituent element different from the first non-metal element and/or the second first non-metal element.

In some embodiments, the second transition metal compound comprises a second transition metal element different from the rare-earth element and/or the metal element.

In some embodiments, the second transition metal compound is implemented as a second transition metal carbide and/or a second transition metal nitride. Suitable transition metal carbides for use as a second transition metal compound include TiC, VC, HfC, TaC, ZrC, ScC, NbC. Suitable transition metal nitrides for use as a second transition metal compound include TiN, ZrN, HAN, VN, Mo, NbN, TaN, ScN, CrN, MON, and WN. In some embodiments, the second transition metal compound is implemented as titanium nitride or as titanium carbide.

In some embodiments, the first conductive layer and/or second conductive layer comprises a metal. Suitable metals include Cu, Co, Al, V, Cr, Y, Re, Ru, Mo, W, and Ti.

It shall be understood that when a rare-earth-containing layer is deposited on a first conductive layer, and/or when a second conductive layer is deposited on the rare-earth-containing layer, intermixing of those layer's constituent components may occur, for example, by means of diffusion, surface segregation, or another process. In some embodiments, such intermixing can result in the formation of an interlayer containing both components of the conductive layer and the rare-earth-containing layer. In some embodiments, such intermixing can result in alloying or doping of the rare-earth-containing layer.

In some embodiments, the second conductive layer has a thickness greater than or equal to 0.5 nm, or to 1 nm, or to 2nm and/or less than or equal to 40 nm, or to 30 nm or to 20 nm.

In some embodiments, the process of depositing the rare-earth-containing layer comprises providing a first hydrogen-containing substance after the process of providing a rare-earth precursor and/or providing a second hydrogen-containing substance after the process of providing a metal precursor.

In some embodiments, the first hydrogen-containing substance and/or the second hydrogen-containing substance comprises hydrogen gas.

In some embodiments, providing a first hydrogen-containing substance after providing a rare-earth precursor and/or providing a second hydrogen-containing substance after providing a metal precursor may enable controlling the rare earth metal and carbon content of a rare- earth-containing layer. Without the presently disclosed subject matter being bound by any particular theory or mode of operation, it is believed that provision of hydrogen may result in a weakening and/or breaking of chemical bonds between a rare-earth element and ligands in a rare-earth precursor or a metal element and ligands in a metal precursor. Additionally alternatively, it is believed that the provision of hydrogen may transform carbon-and hydrogen-containing ligands into volatile by-products, such as CH4, which are readily removed from a process chamber. Thus, provision of hydrogen may advantageously allow for removal of residual carbon.

It shall be understood that any successive processes, steps, and/or pulses may or may not be separated by a purge. In some embodiments, processes of providing a rare-earth precursor and providing a metal precursor may be separated by a purge. In some embodiments, providing a rare-earth precursor and providing a first non-metal element reactant may be separated by a purge. In some embodiments, providing a rare-earth precursor and providing a second non-metal element reactant may be separated by a purge. In some embodiments, providing a rare-earth precursor and providing a non-metal multi-element reactant may be separated by a purge. In some embodiments, providing a metal precursor and providing a first non-metal element reactant may be separated by a purge. In some embodiments, providing a metal precursor and providing a second non-metal element reactant may be separated by a purge. In some embodiments, providing a metal precursor and providing a non-metal multi-element reactant may be separated by a purge. In some embodiments, providing a first non-metal element reactant and providing a second non-metal element reactant may be separated by a purge. In some embodiments, providing a first non-metal element reactant and providing a non-metal multi-element reactant may be separated by a purge. In some embodiments, providing a second non-metal element reactant and providing a non-metal multi-element reactant may be separated by a purge.

In some embodiments, the rare-earth-containing layer is formed at a deposition temperature greater than or equal to 100° C., or 200° C., or 300° C., or 350° C. and/or less than or equal to 550° C., or to 500° C., or to 450° C., or to 400° C. In some embodiments, wherein the rare-earth-containing layer may or may not be formed at such a deposition temperature, activation energy for driving chemical reactions necessary to form the rare-earth-containing layer may be supplied at least partly by non-thermal means, e.g., using electromagnetic radiation.

In some embodiments, the rare-earth-containing layer is deposited at a pressure of at least 0.01 Torr to at most 100 Torr, or at a pressure of at least 0.1 Torr to at most 50 Torr, or at a pressure of at least 0.5 Torr to at most 25 Torr, or at a pressure of at least 1 Torr to at most 10 Torr, or at a pressure of at least 2 Torr to at most 5 Torr.

In some embodiments, the rare-earth-containing layer has a thickness greater than or equal to 0.1 nm, or to 0.5 nm, or to 1 nm, or to 2 nm and/or less than or equal to 10 nm, or to 8 nm, or to 5 nm.

The rare-earth-containing layer can be formed in any suitable process chamber. In some embodiments, the rare-earth-containing layer is formed in a cross-flow process chamber, a showerhead process chamber, or a hot-wall process chamber. In some embodiments, the rare-earth-containing layer may be formed in a single-substrate process chamber, whereas in other embodiments the rare-earth-containing layer may be formed in a multi-substrate, e.g., batch, process chamber.

In some embodiments, the process of providing a rare-earth precursor comprises holding the rare-earth precursor in a rare-earth precursor vessel and transporting the rare-earth precursor to the process chamber using a rare-earth precursor carrier gas, and/or the process of providing a metal precursor comprises holding the metal precursor in a metal precursor vessel and transporting the metal precursor to the process chamber using a metal precursor carrier gas.

In some embodiments, the rare-earth precursor carrier gas and/or the metal precursor carrier gas is independently selected from the group consisting of nitrogen gas, helium gas, neon gas, argon gas, krypton gas, xenon gas, radon gas, and mixtures thereof. In some embodiments, for example, when a rare-earth precursor and/or a metal precursor has a sufficiently high vapor pressure at a suitable temperature, the use of one or more of such carrier gases may be omitted.

In some embodiments, the rare-earth precursor vessel is configured for cooling the rare-earth precursor. In some embodiments, the rare-earth precursor vessel is configured for heating the rare-earth precursor. In some embodiments, metal precursor vessel is configured for cooling the metal precursor. In some embodiments, the metal precursor vessel is configured for heating the metal precursor.

In some embodiments, the rare-earth precursor and/or the metal precursor is held at a vessel temperature greater than or equal to 20° C., or 50° C., or 70° C., or 350° C. and/or less than or equal to 200° C., or to 150° C., or to 130° C. In some embodiments, the vessel temperature is selected to affect vaporization and/or sublimation of the rare-earth precursor and/or the metal precursor.

In some embodiments, the process of depositing the rare-earth-containing layer is implemented as a chemical vapor deposition process, for example, a cyclic chemical vapor deposition process, such as an atomic layer deposition process, e.g., a temporal atomic layer deposition process. In some embodiments, the chemical vapor deposition process comprises one or more cycles. Typically, each cycle of said one or more cycles comprises two or more pulses. In some embodiments, at least one pulse of said two or more pulses involves a self-limiting surface reaction. In some embodiments, each pulse of said two or more pulses involves a self-limiting surface reaction.

In some embodiments, a rare-earth precursor pulse and/or a metal precursor pulse lasts from at least 0.01 s to at most 120 s, or from at least 0.01 s to at most 0.1 s, or from at least 0.01 s to at most 0.02 s, or from at least 0.02 s to at most 0.05 s, or from at least 0.05 s to at most 0.1 s, or from at least 0.1 s to at most 20 s, or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s.

In some embodiments, a non-metal element reactant pulse, e.g., a first non-metal element reactant pulse, a second non-metal element reactant pulse, and/or a non-metal multi-element reactant pulse, lasts from at least 0.1 s to at most 20 s or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s, or from at least 20.0 s to at most 120.0 s, or from at least 20.0 s to at most 50.0 s, or from at least 50.0 s to at most 80.0 s, or from at least 80.0 s to at most 120.0 s.

In some embodiments, the process of depositing the rare-earth-containing layer is implemented as a thermal deposition process or an active-species-enhanced deposition process, such as a radical-enhanced deposition process.

In case the process of depositing the rare-earth-containing layer is implemented as a thermal deposition process, durations of the processes of providing a rare-earth precursor, providing a metal precursor, providing one or more non-metal element reactants, providing a first hydrogen-containing substance, and/or providing a second hydrogen-containing substance may be relatively long. For example, one or more of said durations may be greater than or equal to 5 s or to 10 s or from about 5 s to about 10 s.

In some embodiments, the substrate is subjected to an annealing step in an ambient comprising hydrogen and nitrogen, ammonia (NH₃), and/or argon after the process of depositing the rare-earth-containing layer. Suitably, the annealing step may be conducted at a temperature from at least 300° C. to at most 600° C. Alternatively, the annealing step can be conducted at a temperature from at least 300° C. to at most 1300° C., 1200° C., or 1100° C.

In some embodiments, the presently described methods may be used to form a metal gate electrode for a CMOS, e.g., n-MOS or p-MOS, transistor.

Further described herein is an apparatus. The apparatus comprises a process chamber, a precursor supply unit for supplying a rare-earth precursor and a metal precursor in the process chamber, a reactant supply unit for supplying one or more non-metal element reactants into the process chamber, and a control unit configured to control at least the precursor supply unit and the reactant supply unit to conduct any method in accordance with this specification.

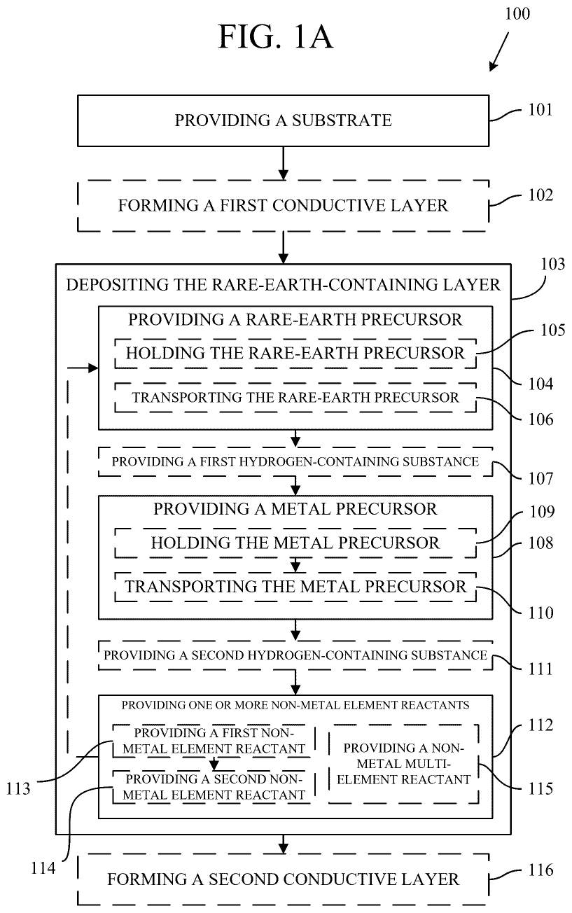

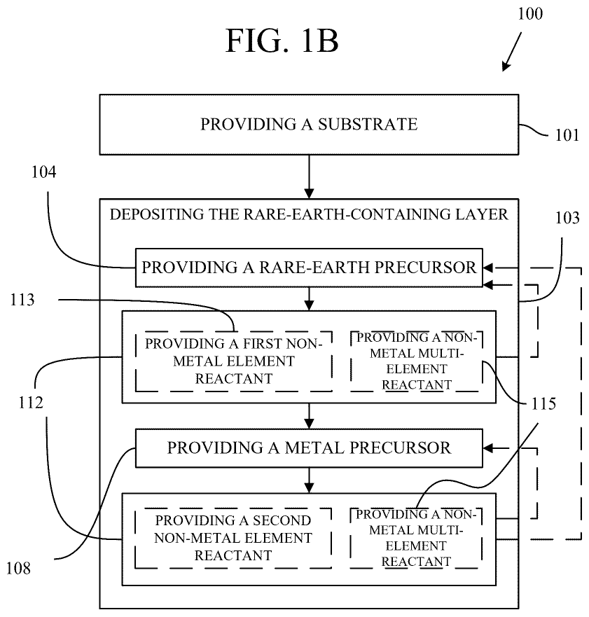

Turning now to the figures, FIG. 1A illustrates a method 100 for forming a rare-earth-containing layer according to an embodiment. Unless explicitly stated otherwise, the method 100 of the embodiment of FIG. 1A may or may not comprise any feature(s) disclosed within this specification.

The method 100 of the embodiment of FIG. 1A comprises providing a substrate within a process chamber, optionally forming a first conductive layer 102, depositing the rare-earth-containing layer 103 over the substrate after forming a first conductive layer 102, and optionally forming a second conductive layer 116 after depositing the rare-earth-containing layer 103. The rare-earth-containing layer formed by means of the method 100 comprises a rare-earth element, e.g., cerium; a metal element different from the rare-earth element, e.g., erbium; a first non-metal element, e.g., carbon; and a second non-metal element different from the first non-metal element, e.g., sulfur.

The process of depositing the rare-earth-containing layer 103 of the embodiment of FIG. 1A comprises providing a rare-earth precursor 104, e.g., tris(isopropylcyclopentadienyl)cerium (Ce (iPrCp)₃), into the process chamber; optionally providing a first hydrogen-containing substance 107, e.g., hydrogen gas (H₂), after the process of providing a rare-earth precursor 104; providing a metal precursor 108, e.g., tris(isopropylcyclopentadienyl)erbium (Er(iPrCp)₃), into the process chamber; optionally providing a second hydrogen-containing substance 111, e.g., hydrogen gas (H₂), after the process of providing a metal precursor 108, and providing one or more non-metal element reactants 112 into the process chamber.

In the embodiment of FIG. 1A, the process of providing a rare-earth precursor 104 of the may comprise holding the rare-earth precursor 105 in a rare-earth precursor vessel and transporting the rare-earth precursor 106 to the process chamber using a rare-earth precursor carrier gas, and the process of providing a metal precursor 108 may comprise holding the metal precursor 109 in a metal precursor vessel and transporting the metal precursor 110 to the process chamber using a metal precursor carrier gas.

Further, the process of providing one or more non-metal element reactants 112 of the embodiment of FIG. 1A may comprise providing a first non-metal element reactant 113, e.g., diiodoethane, and providing a second non-metal element reactant 114, e.g., hydrogen sulfide (H₂S), different from the first non-metal element reactant. Additionally or alternatively, the process of providing one or more non-metal element reactants 112 may comprise providing a non-metal multi-element reactant 115, e.g., dimethyl sulfide (DMS, (CH₃)₂S), comprising the first non-metal element and the second first non-metal element.

As indicated in FIG. 1A using a dashed arrow, the process of depositing the rare-earth-containing layer 103 may be implemented as cyclic chemical vapor deposition process. Additionally or alternatively, the method 100 may comprise purging steps between any or all of the processes described above. The process of depositing the rare-earth-containing layer 103 of the embodiment of FIG. 1A may be implemented as a temporal atomic layer deposition process.

FIG. 1B illustrates at least part of a method 100 for forming a rare-earth-containing layer according to another embodiment. Unless explicitly stated otherwise, the method 100 of the embodiment of FIG. 1B may or may not comprise any feature(s) of the method 100 of the embodiment of FIG. 1A disclosed above and/or any feature(s) disclosed within this specification.

The method 100 of the embodiment of FIG. 1B comprises providing a substrate within a process chamber and depositing the rare-earth-containing layer 103 over the substrate. The rare-earth-containing layer formed by means of the method 100 comprises a rare-earth element, a metal element different from the rare-earth element, a first non-metal element, and a second non-metal element different from the first non-metal element.

The process of depositing the rare-earth-containing layer 103 of the embodiment of FIG. 1B comprises providing a rare-earth precursor 104 into the process chamber, providing a metal precursor 108 into the process chamber, and providing one or more non-metal element reactants 112 into the process chamber.

In the embodiment of FIG. 1B, the process of providing one or more non-metal element reactants 112 may comprise providing a first non-metal element reactant 113 after the process of providing a rare-earth precursor 104 and providing a second non-metal element reactant 114 different from the first non-metal element reactant after the process of providing a metal precursor 108. Additionally or alternatively, the process of providing one or more non-metal element reactants 112 may comprise providing a non-metal multi-element reactant 115 comprising the first non-metal element and the second first non-metal element after the process of providing a rare-earth precursor 104 and/or after the process of providing a metal precursor 108.

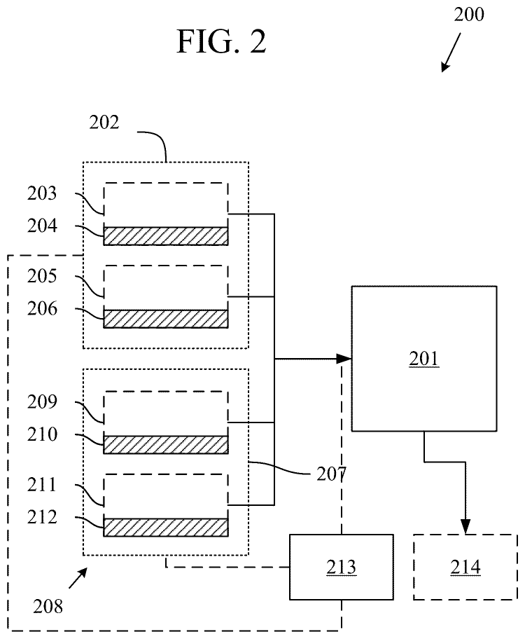

FIG. 2 depicts an apparatus 200 according to an embodiment. The apparatus 200 of the embodiment of FIG. 2, which may be implemented, for example, as an atomic layer deposition apparatus, such as a temporal atomic layer deposition apparatus, comprises a process chamber 201, a precursor supply unit 202 for supplying a rare-earth precursor 204 and a metal precursor 206 into the process chamber 201, a reactant supply unit 207 for supplying one or more non-metal element reactants 208 into the process chamber 201, and a control unit 213 configured to control at least the precursor supply unit 202 and the reactant supply unit 207 to conduct a method in accordance with the present disclosure. The apparatus 200 may further comprise an exhaust unit 214 suitable for or configured to remove fluid and/or fluid-like substance(s), e.g., precursor(s), reactant(s), reaction by-product(s), from the process chamber 201 and/or to maintain pressure within the process chamber 201 at a pre-determined pressure range, e.g., at reduced pressures or at sub-atmospheric pressures.

In the embodiment of FIG. 2, the precursor supply unit 202 may comprise a rare-earth precursor vessel 203 for storing the rare-earth precursor 204, a metal precursor vessel 205 for storing the metal precursor 206, a first non-metal element reactant vessel 209 for storing a first non-metal element reactant 210, and/or a second non-metal element reactant vessel 211 for storing a second non-metal element reactant 212.

The process chamber 201 of the embodiment of FIG. 2 may be implemented as any suitable type of process chamber, for example, as a cross-flow process chamber, a showerhead process chamber, or a hot-wall process chamber.

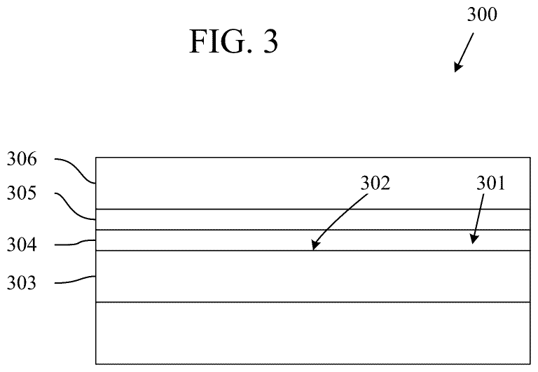

FIG. 3 shows a partial cross-sectional view of a structure 300 according to an embodiment. The structure 300 of the embodiment of FIG. 3 may be formed using a method in accordance with the first aspect.

The structure 300 of the embodiment of FIG. 3 comprises a substrate 301 and a rare-earth-containing layer 305 over the substrate 301. The rare-earth-containing layer 305 comprises a rare-earth element, e.g., cerium; a metal element different from the rare-earth element, e.g., erbium; a first non-metal element, e.g., carbon; and a second non-metal element different from the first non-metal element, e.g., sulfur.

In the embodiment of FIG. 3, the structure 300 may form at least part of a semiconductor device, such as a semiconductor transistor, e.g., a metal-oxide-semiconductor field-effect transistor.

The substrate 301 of the embodiment of FIG. 3 has an outer surface 302 and comprises a dielectric layer 303 extending along the outer surface 302. The dielectric layer 303 may comprise, for example, hafnium dioxide.

In the embodiment of FIG. 3, the structure 300 further comprises a first conductive layer 304 between the substrate 301 and the rare-earth-containing layer 305 as well as a second conductive layer 306 over the rare-earth-containing layer 305. Each of the first conductive layer 304 and the second conductive layer 306 may comprise titanium nitride. One or more of the first conductive layer 304 and the second conductive layer 306 may further comprise titanium carbide.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for forming a rare-earth-containing layer, the method comprising:
providing a substrate within a process chamber; and
depositing the rare-earth-containing layer over the substrate, the method of depositing the rare-earth-containing layer comprising:
i) providing a rare-earth precursor into the process chamber,
ii) providing a metal precursor into the process chamber, and
iii) providing one or more non-metal element reactants into the process chamber,
wherein the rare-earth-containing layer comprises a rare-earth element, a metal element different from the rare-earth element, a first non-metal element, and a second non-metal element different from the first non-metal element.

2. A method according to claim 1, wherein the rare-earth element is selected from the group consisting of cerium, dysprosium, erbium, europium, gadolinium, holmium, lanthanum, lutetium, neodymium, praseodymium, promethium, samarium, scandium, terbium, thulium, ytterbium, and yttrium.

3. A method according to claim 1, wherein the rare-earth precursor comprises at least one of cerium, dysprosium, erbium, europium, gadolinium, holmium, lanthanum, lutetium, neodymium, praseodymium, promethium, samarium, scandium, terbium, thulium, ytterbium, and yttrium.

4. A method according to claim 1, wherein the rare-earth precursor comprises the rare-earth element in oxidation state +3 or in oxidation state +4.

5. A method according to claim 1, wherein the rare-earth precursor comprises a cyclopentadienyl ligand, for example, an unsubstituted cyclopentadienyl ligand or a substituted cyclopentadienyl ligand, such as an alkylsilyl-substituted cyclopentadienyl ligand, e.g., an isopropylcyclopentadienyl ligand.

6. A method according to claim 1, wherein the metal element is selected from the group consisting of group 3 metals, e.g., scandium and yttrium; group 4 metals, e.g., titanium and zirconium; group 5 metals, e.g., vanadium and niobium; group 6 metals, e.g., chromium and molybdenum; group 7 metals, e.g. manganese; group 8 metals, e.g., iron and ruthenium; group 9 metals, e.g., cobalt and rhodium; group 10 metals, e.g., nickel and palladium; group 11 metals, e.g., copper and silver; group 12 metals, e.g., zinc and cadmium; group 13 metals, e.g., aluminium, gallium, and indium; and lanthanides; e.g., cerium, dysprosium, erbium, europium, gadolinium, holmium, lanthanum, lutetium, neodymium, praseodymium, promethium, samarium, terbium, thulium, and ytterbium.

7. A method according to claim 1, wherein the metal precursor comprises at least one of a group 3 metal, e.g., scandium or yttrium; a group 4 metal, e.g., titanium or zirconium; a group 5 metal, e.g., vanadium or niobium; a group 6 metal, e.g., chromium or molybdenum; a group 7 metal, e.g. manganese; a group 8 metal, e.g., iron or ruthenium; a group 9 metal, e.g., cobalt or rhodium; a group 10 metal, e.g., nickel or palladium; a group 11 metal, e.g., copper or silver; a group 12 metal, e.g., zinc or cadmium; a group 13 metal, e.g., aluminium, gallium, or indium; and lanthanides; e.g., cerium, dysprosium, erbium, europium, gadolinium, holmium, lanthanum, lutetium, neodymium, praseodymium, promethium, samarium, terbium, thulium, or ytterbium.

8. A method according to claim 1, wherein the metal precursor comprises the metal element in oxidation state +3 or in oxidation state +4.

9. A method according to claim 1, wherein the metal precursor comprises a cyclopentadienyl ligand, for example, an unsubstituted cyclopentadienyl ligand or a substituted cyclopentadienyl ligand, such as an alkylsilyl-substituted cyclopentadienyl ligand, e.g., an isopropylcyclopentadienyl ligand.

10. A method according to claim 1, wherein the first non-metal element and/or the second non-metal element is selected from the group consisting of boron, group 14 non-metals, e.g., carbon or silicon; group 15 non-metals, e.g., nitrogen, phosphorus, or arsenide; group 16non-metals, e.g., oxygen, sulfur, selenium, or tellurium; and group 17 non-metals, e.g., fluorine, chlorine, bromine, or iodine.

11. A method according to claim 1, wherein the method of providing one or more non-metal element reactants comprises providing a first non-metal element reactant and providing a second non-metal element reactant different from the first non-metal element reactant.

12. A method according to claim 11, wherein the first non-metal element reactant comprises at least one of boron, a group 14 non-metal, e.g., carbon or silicon; a group 15 non-metal, e.g., nitrogen, phosphorus, or arsenide; a group 16 non-metal, e.g., oxygen, sulfur, selenium, or tellurium; and a group 17 non-metal, e.g., fluorine, chlorine, bromine, or iodine; and the second non-metal element reactant comprises at least one other of boron, a group 14 non-metal, e.g., carbon or silicon; a group 15 non-metal, e.g., nitrogen, phosphorus, or arsenide; a group 16 non-metal, e.g., oxygen, sulfur, selenium, or tellurium; and a group 17 non-metal, e.g., fluorine, chlorine, bromine, or iodine.

13. A method according to claim 1, wherein the method of providing one or more non-metal element reactants comprises providing a non-metal multi-element reactant comprising the first non-metal element and the second non-metal element.

14. A method according to claim 1, wherein the substrate has an outer surface and comprises a dielectric layer extending along the outer surface.

15. A method according to claim 14, wherein the dielectric layer comprises a high-k dielectric material, for example, a high-k silicate, e.g., hafnium silicate; a high-k oxide, e.g., hafnium dioxide, tantalum oxide, or zirconium dioxide; or a mixture, e.g., a solid solution or mixed oxide, thereof.

16. A method according to claim 1, wherein the method comprises forming a first conductive layer prior to depositing the rare-earth-containing layer.

17. A method according to claim 16, wherein the first conductive layer comprises a first transition metal compound.

18. A method according to claim 17, wherein the first transition metal compound comprises a first non-metal constituent element different from the first non-metal element and/or the second non-metal element.

19. A method according to claim 17, wherein the first transition metal compound comprises a first transition metal element different from the rare-earth element and/or the metal element.

20. A method according to claim 17, wherein the first transition metal compound is implemented as a first transition metal carbide and/or a first transition metal nitride.
